(19) United States
(12) Patent Application Publication
(10) Pub. No.: US 2008/0057413 A1
(43) Pub. Date: Mar. 6, 2008

(54) PHOTOMASK FOR FORMING MICRO-PATTERNS OF SEMICONDUCTOR DEVICES AND METHOD FOR MANUFACTURING THE SAME

(76) Inventor: Yeon-Ah Shim, Jeothanam-do (KR)

Correspondence Address: SHERR & NOURSE, PLLC, 620 HERNDON PARKWAY, SUITE 200, HERNDON, VA, 20170, US

(21) Appl. No.: 11/844,395

(22) Filed: Aug. 24, 2007

(30) Foreign Application Priority Data
Aug. 31, 2006 (KR) 10-2006-0083424

(51) Int. Cl. G03F 1/00

(52) U.S. Cl. 430/5

(57) ABSTRACT

A method of manufacturing a photomask for forming micro-patterns on a semiconductor device including detecting a shifter-pattern area that encounters a side lobe in a photomask composed of a mask substrate and a shifter pattern deposited on the mask substrate; and forming at least one side lobe-prevention contact hole in the detected shifter-pattern area.

The present application claims priority under 35 U.S.C. 119 to Korean Patent Application No. P 2006-83424 (filed on Aug. 31, 2006), which is hereby incorporated by reference in its entirety.

### BACKGROUND

In semiconductor technology, the smaller the semiconductor device, the higher the integration degree of the semiconductor device. As a result, electronic appliances of small size and lightweight can be manufactured. The design rules are gradually reduced, and the proximity effect occurs, such that it may become difficult to implement a fine pattern such as a micro-pattern. Accordingly, extensive research is conducted in the area of resolution enhancement techniques (RET). A representative RET is an attenuated phase shifter mask (attPSM). The attPSM technique forms a pattern on a mask using a specific material having a phase of 180° at a predetermined transmission rate, instead of using a material such as chromium (Cr) having a transmission rate of approximately 0%. An attPSM technique may permit a pattern edge to have zero intensity such that it increases the contrast and resolution. This may result in improvement of a process margin.

The attPSM technique, however, has been widely used to form a metal wiring or a contact hole from among micro-patterns of less than 130 nm. If micro-patterns having larger size are applied to form the contact hole results in the formation of undesirable side lobes. As illustrated in example FIG. 1, if the crowded contact holes are directly light-exposed to form the pattern, the side lobes form undesired patterns between contact holes. These patterns are formed by a diffraction and interference phenomenon caused by peripheral patterns, and a bridge between the contact holes occurs in a post-process.

Research has been conducted into providing a method for removing side lobes. One method involves pre-forming the chromium (Cr) material for perfectly blocking the light at a specific part at which the side lobe will occur so as to prevent the formation of side lobes. This method, however, complicates the overall mask structure, and results in a difficult and complicated mask manufacturing process.

### SUMMARY

Embodiments relate to a method of forming a photomask including detecting a shifter-pattern area for encountering a side lobe in a photomask composed of a mask substrate and a shifter pattern deposited on and/or over the mask substrate; and forming at least one side lobe-prevention contact hole in the shifter-pattern area.

Embodiments relate to a photomask including a mask substrate; a plurality of shifter patterns contained in the mask substrate; and at least one side lobe-prevention contact hole contained in the shifter patterns.

### DRAWINGS

FIG. 1 illustrates a side-lobe generated from a pattern.

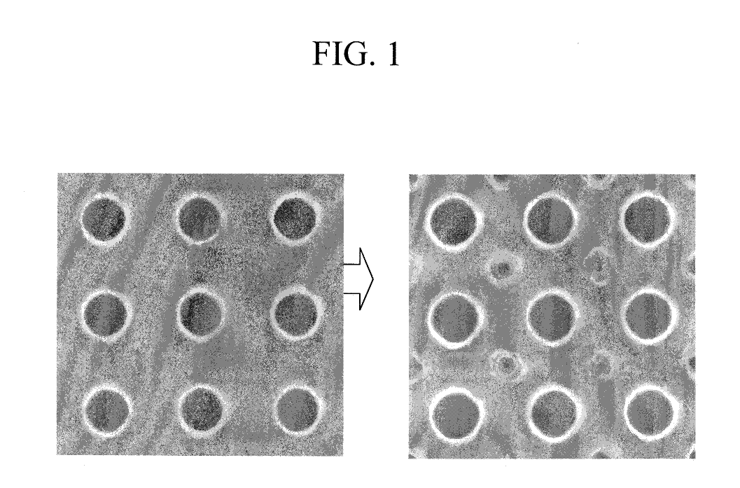

FIGS. 2A to 2B illustrate a method for manufacturing a photomask, in accordance with embodiments.

FIG. 3 is a graph illustrating the light intensity at individual locations of a photomask, in accordance with embodiments.

### DESCRIPTION

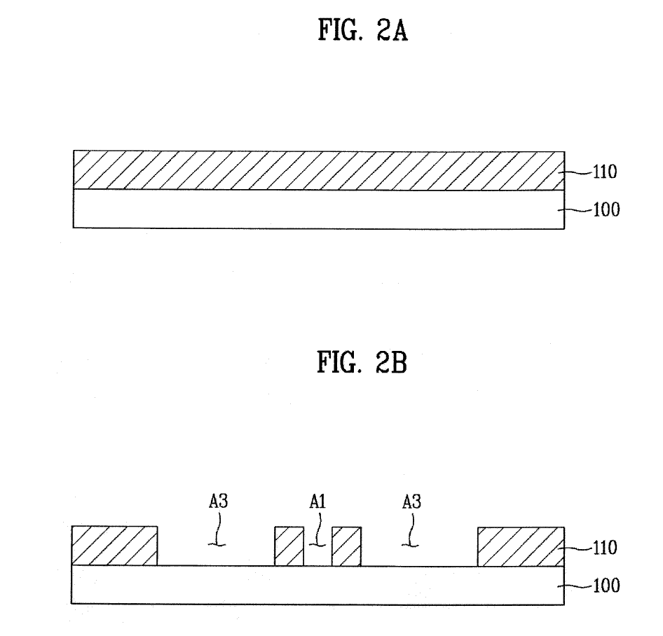

As illustrated in example FIG. 2A, in accordance with embodiments, a silicon dioxide (SiO₂) film is deposited on and/or over mask substrate 100 using a sputtering method. Mask substrate 100 may be composed of quartz or quartz-type material. A spin on glass (SOG) film is formed on and/or over substrate 100 using a spinning method such that shifter layer 110 having a thickness of approximately 4,000 to approximately 4,500 Angstrom is formed. The adhesion of shifter layer 110 to the surface of mask substrate 100 can be enhanced by applying an agent for promoting adhesion such as hexamethyldisilazane (HMDS) on the surface of mask substrate 100.

As illustrated in example FIG. 2B, a photoresist layer is deposited on and/or over shifter layer 110. The photoresist layer can be patterned in the form of a predetermined shape. The resultant photoresist pattern can be used as a mask, and shifter layer 110 can be etched in the form of a pattern using a reactive ion etching (RIE) method based on CF₄- and O₂-based gas.

Side lobe prevention contact hole A1 contained in the pattern of shifter layer 110 is arranged between contact holes A3, and is then patterned. The size of side lobe prevention contact hole A1 may be determined in accordance with a variety of factors. Such factors may include but is not limited to, for example, the size of a side lobe detected by a fabrication or simulation process, a light source of a lithographic process, a critical dimension (CD) of a pattern to be implemented on the semiconductor substrate, and/or a photoresist thickness of the pattern to be implemented on the semiconductor substrate. The size of side lobe-prevention contact hole A1 may be equal to approximately ⅕ to ⅓ times the size of contact holes A3.

If the simulation of contact holes A3 having a size of 0.16 μm to 0.187 μm is driven on the assumption that the 0.5σ to 0.6σ part is used as a light transmission area by a lithographic device having an aperture diameter, the mask area capable of generating the side lobe can be detected, and the size of side lobe prevention contact hole A1 may be set to approximately 0.03 to 0.063 μm compared with contact holes A3 of approximately 0.16 to 0.187 μm in size.

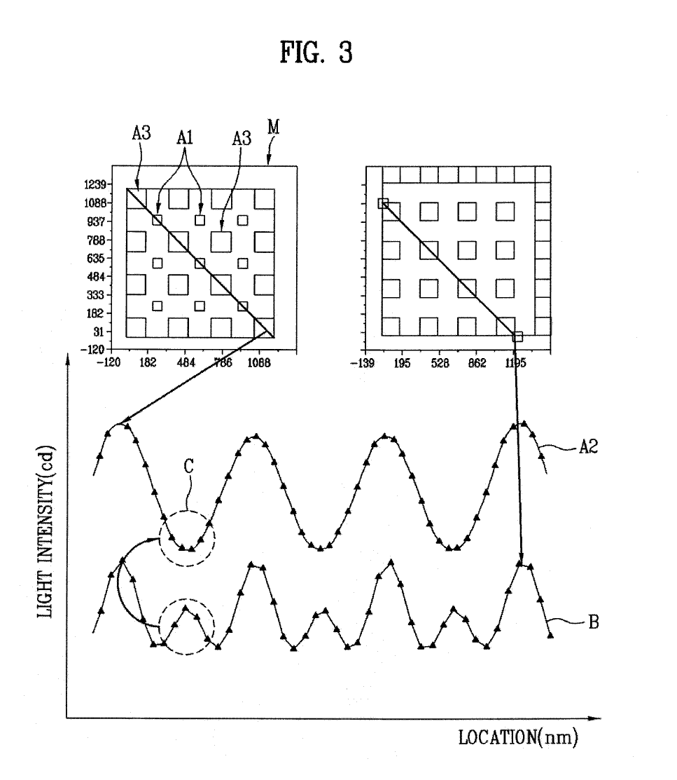

In accordance with embodiments illustrated in example FIG. 3, if a plurality of side lobe prevention contact holes A1 occur in the side lobe-generation area between contact holes A3, patterning can be conducted at light intensity A2. Provided that the side lobe locations can be detected via simulation, and photomask M is formed, photomask M can be included and side lobe prevention contact holes A1 having a size of approximately 0.03 to 0.063 μm formed at the locations. The intensity of the light signal received from peripheral patterns can be compensated, and the light intensity configured in the form of the area denoted at C on A2 illustrated in example FIG. 3 can be applied to a predetermined pattern of the semiconductor substrate.

As illustrated in example FIG. 3, embodiments may include removal of the side lobes generated by the light signals generated at the dashed circular area contained in line B (i.e., the lithographic-light-source graph) in order to ensure a process margin in the contact-hole forming process.

In accordance with embodiments, lithographic and etching processes for patterning a chromium (Cr) material may be removed from the overall photomask manufacturing process. Thus, a method of manufacturing a photomask which prevents the occurrence of side lobes can be applied in a simple manner. Such a method may ensure a process margin in the contact-hole forming process.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
detecting a shifter-pattern area having a side lobe in a photomask composed of a mask substrate and a shifter pattern deposited over the mask substrate, the shifter pattern having at least one contact hole; and
forming at least one side lobe prevention contact hole for preventing side lobe formation in the detected shifter-pattern area.

2. The method of claim 1, wherein said at least one side lobe prevention contact hole has a size formed in a range between approximately ⅕ to ⅓ diameter of the at least contact holes of the shifter pattern.

3. The method of claim 1, wherein the size of the at least one side lobe prevention contact hole is determined by at least one of the size of the side lobe, a wavelength of light exposure light sources, a critical dimension of a pattern to be formed, and a photoresist thickness of the pattern to be formed.

4. The method of claim 1, wherein the shifter pattern is formed by at least one of sputtering a layer of silicon dioxide and spin-coating a layer of spin on glass.

5. The method of claim 4, wherein the shifter pattern has a thickness of approximately 4,000 to approximately 4,500 Angstrom.

6. The method of claim 4, wherein the mask substrate is treated with an agent for promoting adhesion between the mask substrate and the shifter pattern.

7. The method of claim 6, wherein the agent for promoting adhesion comprises hexamethyldisilazane.

8. An apparatus comprising:
a mask substrate;
a plurality of shifter patterns having at least one contact hole provided on the mask substrate; and
at least one side lobe prevention contact hole for preventing side lobe formation provided on the plurality of shifter patterns.

9. The apparatus of claim 8, wherein the side lobe-prevention contact hole is formed having a size between approximately ⅕ to ⅓ of a diameter of the contact hole of the shifter patterns.

10. The apparatus of claim 9, wherein the size of the at least one side lobe prevention contact hole is determined by at least on of the size of the side lobe, a wavelength of light exposure light sources, a critical dimension of a pattern to be formed, and a photoresist thickness of the pattern to be formed.

11. The apparatus of claim 9, wherein the plurality of shifter patterns each have a thickness of approximately 4,000 to approximately 4,500 Angstrom.

12. A method comprising:
providing a photomask including a mask substrate and a shifter pattern deposited over the mask substrate, wherein the shifter pattern includes a plurality of contact holes;
detecting a defecting area of the shifter pattern having a side lobe; and
forming a plurality of side lobe preventing contact holes between the plurality of contact holes in the detected shifter-pattern area.

13. The method of claim 12, wherein the mask substrate comprises quartz.

14. The method of claim 12, wherein the shifter pattern comprises spin on glass.

15. The method of claim 12, wherein the plurality of side lobe prevention contact holes each have a size between approximately ⅕ to ⅓ of a diameter of the plurality contact hole of the shifter pattern.

16. The method of claim 12, wherein the plurality of side lobe prevention contact holes each have a size of between approximately 0.03 μm to approximately 0.063 μm.
